(19) United States
(12) Patent Application Publication
(10) Pub. No.: US 2026/0275489 A1
(43) Pub. Date: Sep. 17, 2026

(54) DEPOSITION APPARATUS AND ELECTRONIC DEVICE INCLUDING DISPLAY PANEL MANUFACTURED BY SHADOW MASK OF THE DEPOSITION APPARATUS

(71) Applicant: Samsung Display Co., LTD., Yongin-si (KR)

(72) Inventor: JEONGWON HAN, Yongin-si (KR)

(21) Appl. No.: 19/447,279

(22) Filed: Jan. 13, 2026

(30) Foreign Application Priority Data
Mar. 14, 2025 (KR) 10-2025-0033244

(51) Int. Cl. C23C 14/04

(52) U.S. Cl. CPC C23C 14/042

(57) ABSTRACT

A deposition apparatus includes a mounting stage, a first fixing chuck disposed on the mounting stage, a mask support attached on the first fixing chuck and defining at least one opening hole therein, a shadow mask disposed on the mask support and defining at least one mask hole therein, a support unit disposed on the mounting stage and supporting a lower portion of the mask support, and a second fixing chuck disposed on the support unit and to which a lower portion of the mask is attached, and the support unit may be adjusting a flatness of the mask support.

This application claims priority to Korean Patent Application No. 10-2025-0033244, filed on Mar. 14, 2025, and all the benefits accruing therefrom under 35 U.S.C. §119, the content of which in its entirety is herein incorporated by reference.

### BACKGROUND

### 1. Field

The disclosure herein relates to a deposition apparatus and an electronic device including a display panel manufactured by a shadow mask of the deposition apparatus.

### 2. Description of the Related Art

Typically, an electronic device, which provides an image to a user, such as a smart phone, a digital camera, a notebook computer, a navigation system, or a smart television, includes a display device for displaying an image. The display device generates an image and provides the generated image to a user through a display screen.

A display device includes a display panel that includes a plurality of pixels to generate an image. Each of the plurality of pixels includes a light-emitting element and a plurality of transistors connected to the light-emitting element. The light-emitting element is driven by the transistors to generate light.

A light-emitting element includes an anode, a cathode, and a light-emitting layer disposed between the anode and the cathode. A hole and an electron are injected into the light-emitting layer respectively from the anode and the cathode to form an exciton, and the light-emitting element emits light when the exciton transitions to a ground state. When light-emitting elements of pixels are manufactured, a shadow mask is disposed on a substrate, and an organic material for forming a light-emitting layer is provided on the substrate through openings in the shadow mask.

### SUMMARY

After the shadow mask is aligned with the substrate, a deposition process is performed for depositing the organic material onto the substrate. When the shadow mask is not properly supported and is deformed or sagged due to gravity during the deposition process, the organic material may not be deposited at the designed position on the substrate.

The disclosure provides a deposition apparatus capable of supporting a shadow mask more stably and an electronic device including a display panel manufactured by the shadow mask of the deposition apparatus.

An embodiment of the inventive concept provides a deposition apparatus including a mounting stage, and a mask assembly disposed on the mounting stage, and the mask assembly includes a first fixing chuck disposed on the mounting stage, a mask support attached on the first fixing chuck and defining at least one opening hole therein, a shadow mask disposed on the mask support and including at least one cell formed therein, a support unit disposed on the mounting stage and supporting a lower portion of the mask support, and a second fixing chuck disposed on the support unit and to which a lower portion of the shadow mask is attached, and the support unit may adjust a flatness of the mask support.

In an embodiment of the inventive concept, a deposition apparatus includes a mounting stage, and a mask assembly disposed on the mounting stage, and the mask assembly includes a fixing chuck disposed on the mounting stage, a shadow mask disposed on the fixing chuck and defining at least one cell therein, and a support unit disposed on the mounting stage and supporting a lower portion of the shadow mask, and the support unit may adjust a flatness of the shadow mask.

In an embodiment of the inventive concept, an electronic device includes a processor, and a display device that receives an image signal from the processor and provides a user with an image corresponding to the image signal, and the display device may include a display panel manufactured by a disposition apparatus including a mounting stage, a first fixing chuck disposed on the mounting stage, a mask support attached on the first fixing chuck and defining at least one opening hole therein, a shadow mask disposed on the mask support and defining at least one mask hole therein, a support unit that is disposed on the mounting stage and supports a lower portion of the mask support and adjusts a flatness of the mask support, and a second fixing chuck disposed on the support unit and to which a lower portion of the mask is attached.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a diagram illustrating an embodiment of a deposition apparatus according to the inventive concept;

FIG. 2 is a plan view of a mask assembly according to a first embodiment of the inventive concept;

FIG. 3AA is a cross-sectional view taken along line A-A' shown in FIG. 2;

FIG. 3AB is an enlarged view of a dashed portion of FIG. 3AA;

FIG. 3B is a cross-sectional view taken along line B-B' shown in FIG. 2;

FIG. 4A is a plan view of an embodiment of a shadow mask according to the inventive concept;

FIG. 4B is an enlarged view of a portion of a cell of the shadow mask of FIG. 4A.

FIG. 5 is a plan view of an embodiment of a mask support according to the inventive concept;

FIG. 6A is a plan view of an embodiment of a first fixing chuck according to the inventive concept;

FIG. 6B is a side view of an embodiment of a first fixing chuck according to the inventive concept;

FIG. 7A is a plan view of an embodiment of a mask assembly according to a second embodiment of the inventive concept;

FIG. 7B is a cross-sectional view taken along line E-E' shown in 7A;

FIG. 8A is a plan view of an embodiment of a mask assembly according to a third embodiment of the inventive concept;

FIG. 8B is a cross-sectional view taken along line F-F' shown in FIG. 8A;

FIG. 9 is a cross-sectional view illustrating another embodiment of an adjustment unit according to the inventive concept;

FIG. 10 is a cross-sectional view illustrating an embodiment of a height adjustment unit according to the inventive concept;

FIG. 11 is a plan view of a mask assembly according to a fourth embodiment of the inventive concept;

FIG. 12A is a cross-sectional view taken along line C-C' shown in FIG. 11;

FIG. 12B is a cross-sectional view taken along line D-D' shown in FIG. 11;

FIG. 13 is a diagram illustrating a state in which a deposition material is provided on a substrate by the deposition apparatus illustrated in FIG. 1;

FIG. 14 is a block diagram of an embodiment of an electronic device according to the inventive concept;

FIG. 15 illustrates schematic views of electronic devices according to various embodiments;

FIG. 16 is an exploded perspective view of an electronic device including a display panel manufactured through a shadow mask of the deposition apparatus illustrated in FIG. 1;

FIG. 17 is a plan view of the display panel illustrated in FIG. 16; and

FIG. 18 is a diagram illustrating an embodiment of a cross-section of a pixel illustrated in FIG. 17.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents.

The term "and/or" includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Hereinafter, in this specification, the wording, “in a plan view”, is defined as a state viewed in a third direction DR3. In addition, the wording, “overlap”, indicates a state in which components overlap with each other in a plan view.

Hereinafter, embodiments of the inventive concept are described with reference to the drawings.

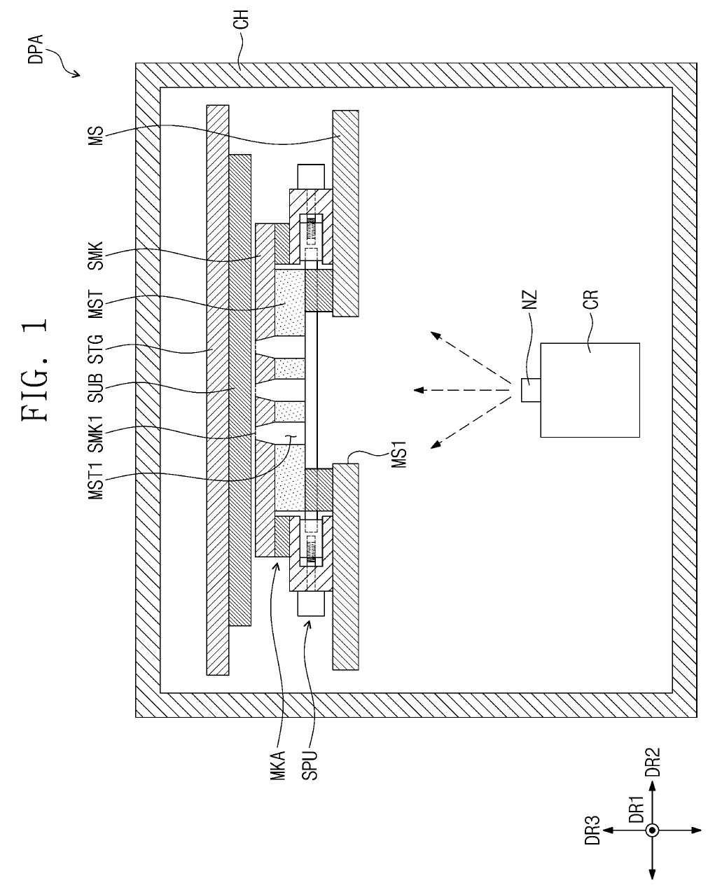

FIG. 1 is a diagram illustrating an embodiment of a deposition apparatus DPA according to the inventive concept.

In an embodiment, FIG. 1 illustrates cross-sections of the deposition apparatus DPA and a mask assembly MKA, as viewed in a first direction DR1.

Referring to FIG. 1, the deposition apparatus DPA may include a chamber CH, a substrate stage STG, a mounting stage MS, a mask assembly MKA, a crucible CR, and a nozzle NZ. The chamber CH may be defined as a vacuum chamber. The substrate stage STG, the mask assembly MKA, the crucible CR, and the nozzle NZ are disposed in the chamber CH.

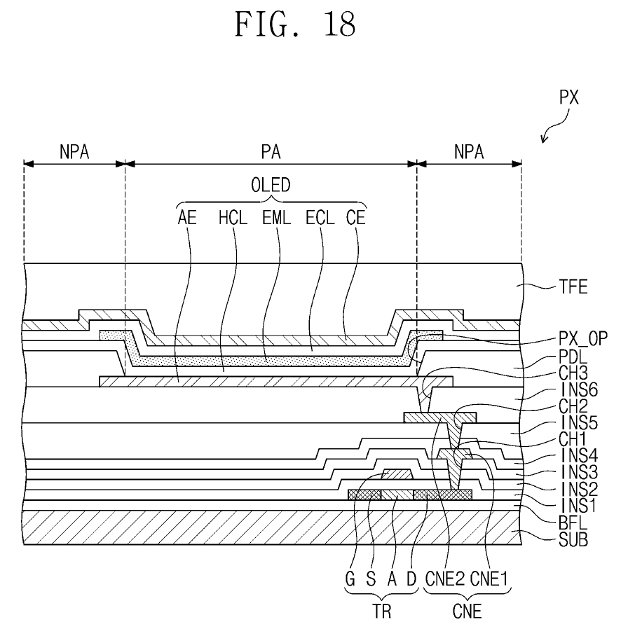

A substrate SUB may be disposed under the substrate stage STG. Although not illustrated in the drawing, vacuum suction holes for suctioning and fixing the substrate SUB may be defined in the substrate stage STG. Additionally, the inventive concept is not limited thereto, and a support unit for supporting opposite sides of the substrate SUB may be used in place of the substrate stage STG. The substrate SUB may be disposed so that a pixel opening PX_OP illustrated in FIG. 18 faces downward.

The mask assembly MKA may be disposed under the substrate SUB. The mask assembly MKA may be disposed next (adjacent) to the substrate SUB. The mask assembly MKA may be disposed on the mounting stage MS that is disposed in the chamber CH.

An opening area MS1, which passes through along the third direction DR3, may be formed in the mounting stage MS. Through the opening area MS1, cells SMK1 of a shadow mask SMK and an opening hole MST1 of the mask support MST may be exposed to the crucible CR and the nozzle NZ.

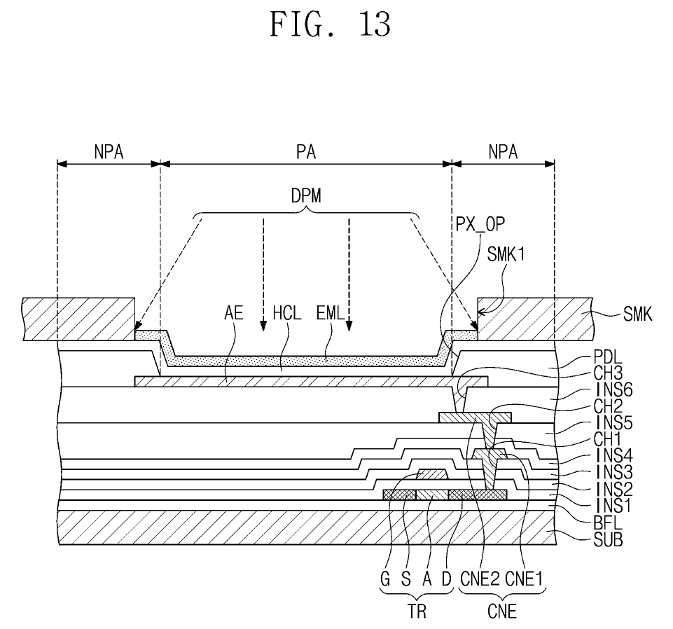

The crucible CR may be disposed below the mask assembly MKA. The mask assembly MKA may be disposed between the substrate stage STG and the crucible CR. Although not illustrated in the drawing, a deposition material DPM (refer to FIG. 13) may be disposed in the crucible CR, and a heating wire may be disposed in the crucible CR to heat the deposition material DPM.

The nozzle NZ may be disposed on the crucible CR. The nozzle NZ may be connected to the crucible CR. The nozzle may be disposed to face the mask assembly MKA.

The deposition material DPM heated in the crucible CR is vaporized, and the vaporized deposition material DPM may be jetted through the nozzle NZ. The deposition material DPM may be deposited on the substrate SUB through the cell SMK1 of the shadow mask SMK.

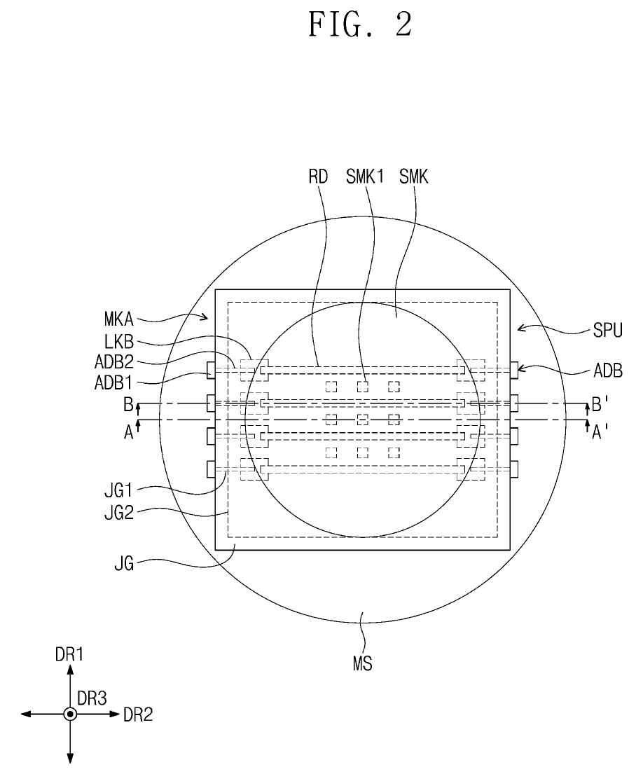

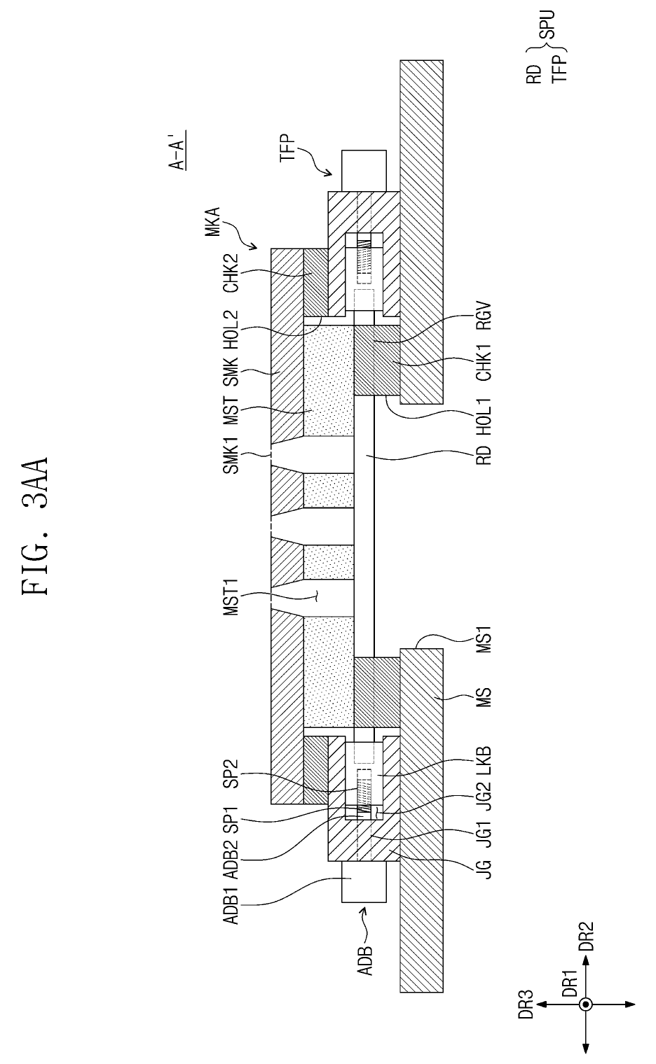

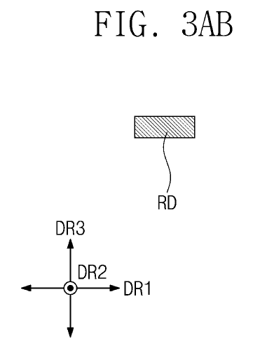

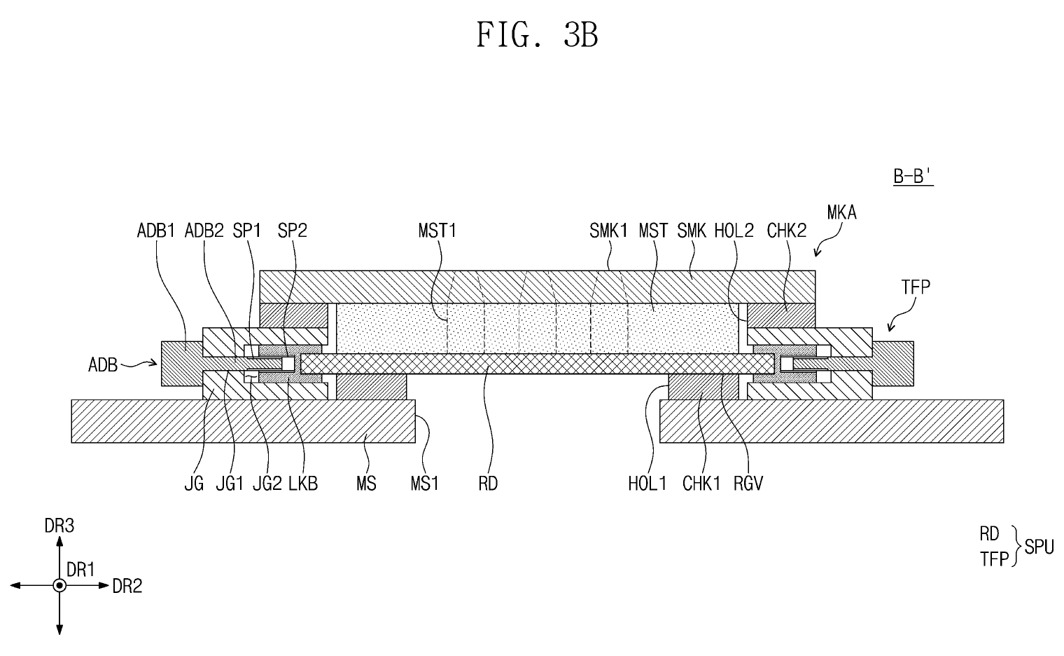

FIG. 2 is a plan view of the mask assembly MKA according to a first embodiment of the inventive concept. FIG. 3AA is a cross-sectional view taken along line A-A' shown in FIG. 2. FIG. 3AB is an enlarged view of a dashed portion of FIG. 3AA. FIG. 3B is a cross-sectional view taken along line B-B' shown in FIG. 2.

Referring to FIGS. 2 to 3B, the mask assembly MKA according to the first embodiment of the inventive concept may include the shadow mask SMK, the mask support MST, a first fixing chuck CHK1, a second fixing chuck CHK2, and a support unit SPU.

The first fixing chuck CHK1 may be disposed on the mounting stage MS. A first chuck hole HOL1 may be defined in a central portion of the first fixing chuck CHK1.

The first fixing chuck CHK1 may be an electrostatic chuck, a magnetic chuck, or the like. When the first fixing chuck CHK1 is the electrostatic chuck, the first fixing chuck CHK1 may include an electrode and the first fixing chuck CHK1 may attract or suction the mask support MST by an electrostatic force. When the first fixing chuck CHK1 is the magnetic chuck, the first fixing chuck CHK1 may include an electromagnet and the first fixing chuck CHK1 may attract or suction the mask support MST by a magnetic force. In addition, the first fixing chuck CHK1 may include various devices capable of fixing the mask support MST by attracting or suctioning the mask support MST.

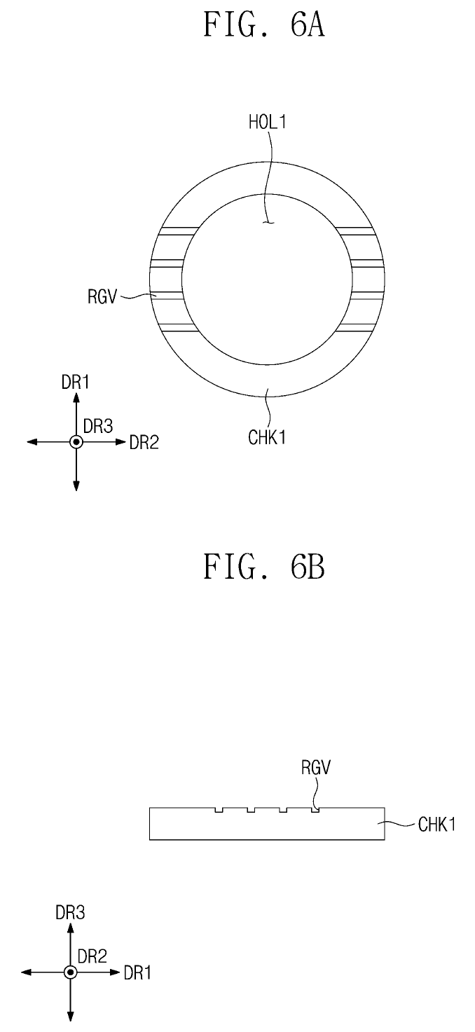

Referring to FIGS. 6A and 6B, the first fixing chuck CHK1 may be substantially disk-shaped but is not limited thereto. Accommodation grooves RGV may be defined in the first fixing chuck CHK1 along a second direction DR2. Support rods RD may be accommodated in the accommodation grooves RGV. The number of the accommodation grooves RGV may correspond to the number of the support rods RD.

The mask support MST may be attached on the first fixing chuck CHK1. The mask support MST may be metallic material that responds to an electric force or magnetic force.

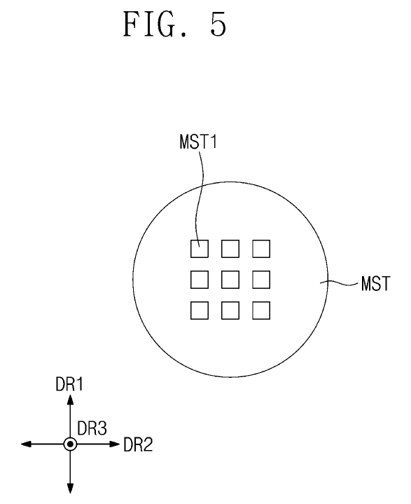

Referring to FIG. 5, in an embodiment of the inventive concept, the mask support MST may be substantially circular-shaped but is not limited thereto. Additionally, at least one or more opening holes MST1 may be defined in the mask support MST. The number of the opening holes MST1 may correspond to the number of the cells SMK1 that are formed on the shadow mask SMK.

Referring to FIGS. 3AA to 3B, the shadow mask SMK may be disposed on the mask support MST. At least one or more cells SMK1 may be formed in the shadow mask SMK. Additionally, the cells SMK1 and the opening holes MST1 may be arranged in overlapping positions in the third direction DR3. The deposition materials jetted from the nozzle NZ may pass through the opening holes MST1 and the cells SMK1, and may be deposited on the substrate SUB. The shadow mask SMK may include metallic material such as tungsten, molybdenum or aluminum, or ceramic material such as aluminum oxide but is not limited thereto.

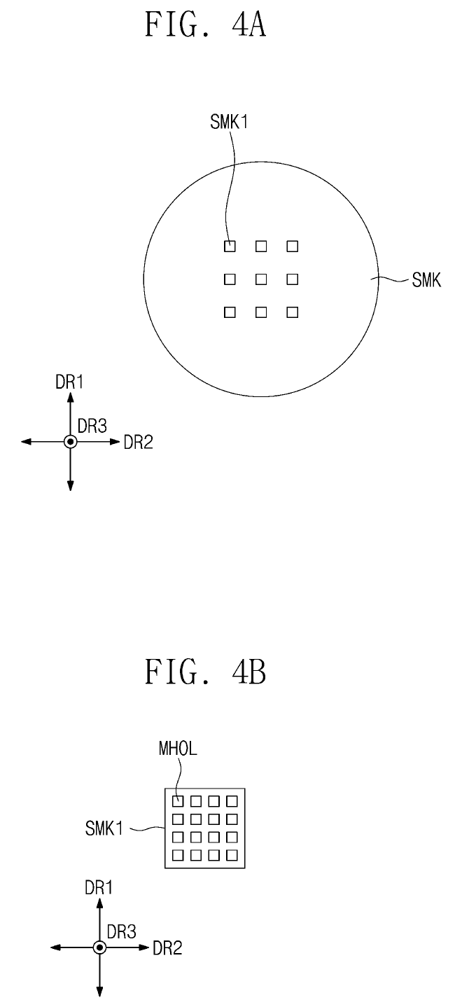

Referring to FIGS. 4A and 4B, the shadow mask SMK may have a circular shape but is not limited thereto. Also, a plurality of mask holes MHOL may be defined in the cell SMK1. The deposition material may be further atomized through the plurality of mask holes MHOL and deposited on the substrate SUB.

The second fixing chuck CHK2 may be disposed on the support unit SPU, and a lower portion of the shadow mask SMK may be attached on the second fixing chuck CHK2. In an embodiment of the inventive concept, the second fixing chuck CHK2 may be substantially disk-shaped but is not limited thereto. A second chuck hole HOL2 may be defined in a central portion of the second fixing chuck CHK2. The mask support MST may be disposed inside the second chuck hole HOL2.

In addition, the second fixing chuck CHK2 may be formed relatively larger than the first fixing chuck CHK1.

The second fixing chuck CHK2 may be an electrostatic chuck, a magnetic chuck, or the like. When the second fixing chuck CHK2 is the electrostatic chuck, the second fixing chuck CHK2 may include an electrode, and the second fixing chuck CHK2 may attract or suction the shadow mask SMK by an electrostatic force. When the second fixing chuck CHK2 is the magnetic chuck, the second fixing chuck CHK2 may include an electromagnet and the second fixing chuck CHK2 may attract or suction the shadow mask SMK by a magnetic force. In addition, the second fixing chuck CHK2 may include various devices capable of fixing the shadow mask SMK by attracting or suctioning the shadow mask SMK.

The support unit SPU may be disposed on the mounting stage MS and support a lower portion of the mask support MST. The support unit SPU may adjust the flatness of the mask support MST.

In an embodiment of the inventive concept, the support unit SPU may include the support rod RD and a tensile force adjustment unit TFP.

The support rod RD may be disposed under the mask support MST, and the support rod RD may contact the lower portion of the mask support MST and support the mask support MST to prevent the mask support MST from being sagged due to gravity. In other words, the support rod RD may support the lower portion of the mask support MST so as to maintain the mask support MST and the shadow mask SMK to be flat. As the mask support MST maintains a flat state, the shadow mask SMK may remain flat.

In an embodiment of the inventive concept, the support rod RD may have a wire-shape extending in the second direction DR2.

The support rod RD may have various cross-sectional shapes. In an embodiment, the support rod RD may have a circular cross-section, an elliptical cross-section, a quadrilateral cross-section, a polygonal cross-section, or the like, for example.

Referring to an enlarged view shown in FIG. 3AB, the support rod RD having a quadrilateral cross-section is shown. In this case, an upper portion of the support rod RD may be flat and suitable for supporting the lower portion of the mask support MST.

Referring to FIG. 2, in a plan view, the support rod RD may be offset with respect to the opening hole MST1 and the cell SMK1. In other words, the support rod RD may be disposed in a position different from the positions of the opening hole MST1 and the cell SMK1 in the third direction DR3. According to this structure, the support rod RD may not obstruct the deposition material from passing through the opening hole MST1 and the cell SMK1.

The tensile force adjustment unit TFP may be disposed on the mounting stage MS and be connected to an edge portion of the support rod RD. The tensile force adjustment unit TFP may be configured to adjust a tensile force of the support rod RD.

The tensile force adjustment unit TFP may be connected to both edge portions of the support rod RD along the second direction DR2. Accordingly, the tensile force adjustment unit TFP may pull the support rod RD from opposite sides thereof to increase the tensile force of the support rod RD.

The tensile force adjustment unit TFP may include a jig JG, a link block LKB, and an adjustment unit ADB and define a jig hole JG1 and a jig groove JG2.

The jig JG may be disposed on the mounting stage MS. Referring to FIG. 2, in an embodiment of the inventive concept, the jig JG may have a quadrilateral shape in a plan view but is not limited thereto. The second fixing chuck CHK2 may be disposed on the jig JG.

The jig hole JG1 may pass through the jig JG in the second direction DR2. The jig hole JG1 may have a circular cross-section to allow a stem part ADB2 of the adjustment unit ADB to rotate.

The jig groove JG2 may be defined inside the jig JG and include an open side that faces the support rod RD.

The link block LKB may be disposed in the jig groove JG2. The link block LKB may move along the second direction DR2 within the jig groove JG2. In an embodiment of the inventive concept, the link block LKB may have a quadrilateral block shape. The edge portion of the support rod RD may be connected to the link block LKB.

The adjustment unit ADB may pass through the jig hole JG1 and be connected to the link block LKB. The adjustment unit ADB may adjust the position of the link block LKB along the second direction DR2.

Referring to FIGS. 3AA to 3B, an embodiment of the adjustment unit ADB may include a head part ADB1, a stem part ADB2, a male screw part SP1, and a female screw part SP2.

The head part ADB1 may be disposed at a side portion of the jig JG. The head part ADB1 may be formed to have a larger size than that of the jig hole JG1.

The stem part ADB2 may be connected to the head part ADB1, and the stem part ADB2 may be connected to the link block LKB through the jig hole JG1. The stem part ADB2 may have a circular cross-section. The diameter of the stem part ADB2 may be equal to, similar to, or slightly smaller than the diameter of the jig hole JG1.

The male screw part SP1 may be disposed on an outer circumferential surface of the stem part ADB2, and the female screw part SP2 may be disposed in the link block LKB. The male screw part SP1 and the female screw part SP2 may be engaged. According to this structure, when the head part ADB1 is rotated, the male screw part SP1 and the female screw part SP2 may be further engaged, and the link block LKB may move toward the head part ADB1. The link block LKB may pull the support rod RD to increase the tensile force of the support rod RD.

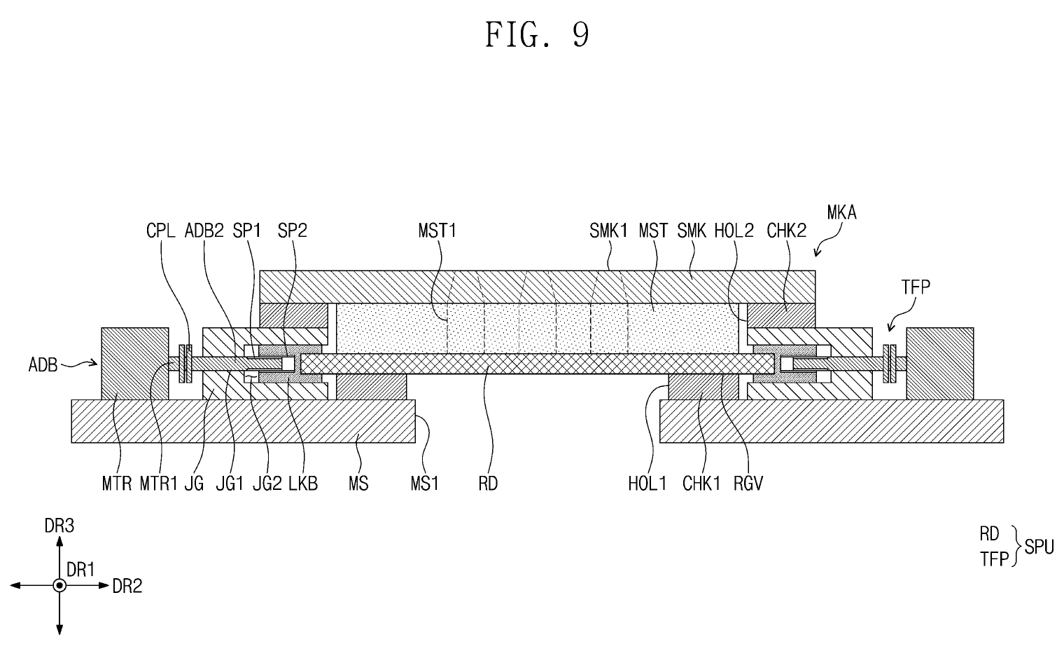

Referring to FIG. 9, another embodiment of the adjustment unit ADB may include a motor MTR, a stem part ADB2, a male screw part SP1, and a female screw part SP2.

The motor MTR may be disposed on the mounting stage MS.

The stem part ADB2 may be connected to a driving shaft MTR1 of the motor MTR by a coupling CPL. The stem part ADB2 may be connected to the link block LKB through the jig hole JG1. The stem part ADB2 may have a circular cross-section. The diameter of the stem part ADB2 may be equal to, similar to, or slightly smaller than the diameter of the jig hole JG1.

The male screw part SP1 may be disposed on the outer circumferential surface of the stem part ADB2, and the female screw part SP2 may be disposed in the link block LKB. The male screw part SP1 and the female screw part SP2 may be engaged. According to this structure, when the motor MTR is rotated, the male screw part SP1 and the female screw part SP2 may be further engaged, and the link block LKB may move toward the head part ADB1. The link block LKB may pull the support rod RD to increase the tensile force of the support rod RD.

In the mask assembly MKA according to the first embodiment of the inventive concept, the adjustment unit ADB may be operated to move the link block LKB, and the link block LKB may pull the support rod RD to increase the tensile force of the support rod RD. The support rod RD, the tensile force of which has been increased, may support the central portion of the mask support MST to prevent the central portion of the mask support MST from being sagged due to gravity. The mask support MST and the shadow mask SMK may be supported to remain flat with relatively high flatness.

The deposition material jetted from the crucible CR and the nozzle NZ may be stably deposited at a designed position on the substrate SUB through the opening hole MST1 of the mask support MST and the cell SMK1 of the shadow mask SMK.

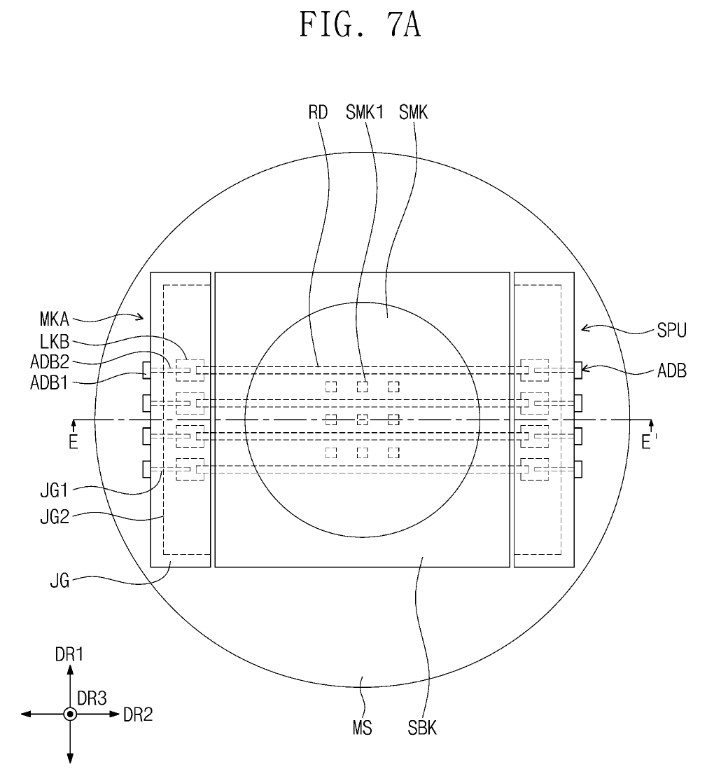

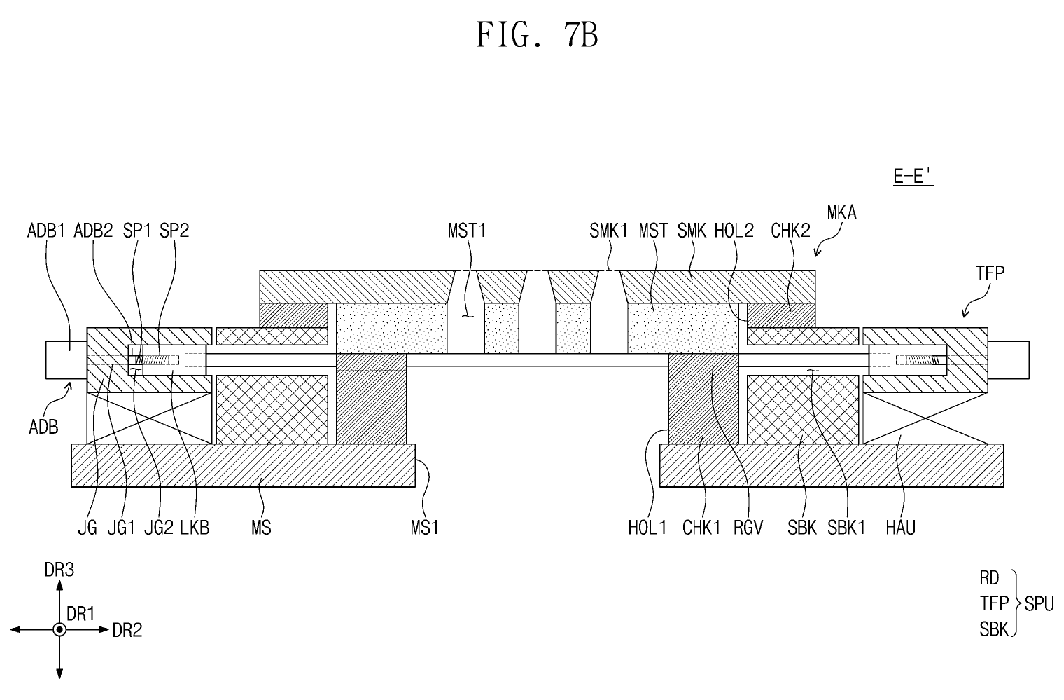

FIG. 7A is a plan view of the mask assembly MKA according to a second embodiment of the inventive concept. FIG. 7B is a cross-sectional view taken along line E-E' shown in FIG. 7A.

Referring to FIGS. 7A and 7B, the mask assembly MKA according to the second embodiment of the inventive concept may include a shadow mask SMK, a mask support MST, a first fixing chuck CHK1, a second fixing chuck CHK2, and a support unit SPU.

Since the configuration of the shadow mask SMK, the mask support MST, the first fixing chuck CHK1, and the second fixing chuck CHK2 is the same as that described in the first embodiment, the above descriptions will be similarly applied thereto.

Additionally, the support unit SPU may include a support rod RD and a tensile force adjustment unit TFP, and the tensile force adjustment unit TFP may include a jig JG, a link block LKB, an adjustment unit ADB, a support block SBK, and a height adjustment unit HAU. Since the configuration of the support rod RD, the jig JG, the link block LKB, and the adjustment unit ADB is the same as that described in the first embodiment, the above descriptions will be similarly applied thereto.

Hereinafter, the support block SBK and the height adjustment unit HAU are to be described.

The support block SBK may be disposed on the mounting stage MS. A block hole SBK1 may be defined in the support block SBK along a second direction DR2. The support rod RD may be disposed passing through the block hole SBK1 and be connected to the link block LKB.

Unlike the first embodiment, the second fixing chuck CHK2 may be disposed on the support block SBK in the mask assembly MKA according to the second embodiment of the inventive concept. The jig JG and the adjustment unit ADB may be disposed on the height adjustment unit HAU. This structure makes it possible to adjust the heights of the jig JG and the adjustment unit ADB, thereby adjusting the position of the support rod RD along a third direction DR3.

In an embodiment, when the support rod RD is not in contact with the lower portion of the mask support MST, the height adjustment unit HAU may be operated to move the support rod RD toward the mask support MST, for example. In other words, the height adjustment unit HAU may adjust the heights of the jig JG and the adjustment unit ADB until the support rod RD contacts the mask support MST.

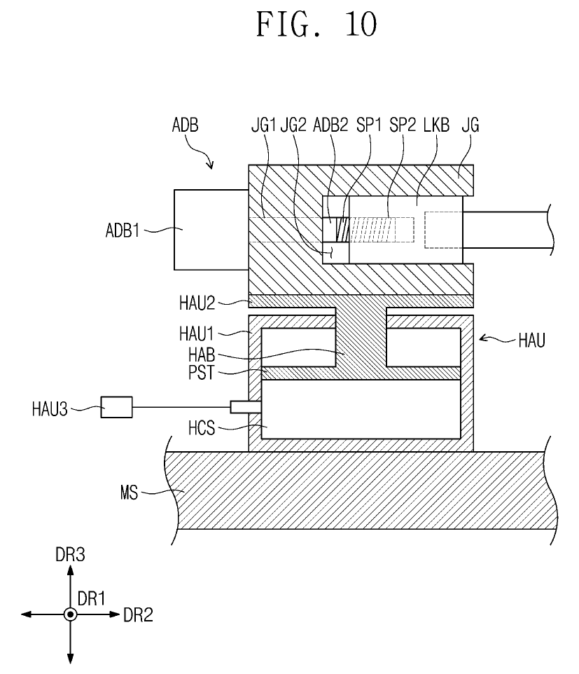

Referring to FIG. 10, the height adjustment unit HAU adjusts the heights of the jig JG and the adjustment unit ADB, thereby adjusting the height of the support rod RD. The height adjustment unit HAU may be implemented with various driving devices that may adjust the height.

In an embodiment of the inventive concept, the height adjustment unit HAU may include a hydraulic cylinder HAU1 and a height adjustment plate HAU2.

A predetermined hydraulic space HCS may be defined inside the hydraulic cylinder HAU1. The hydraulic space HCS may be connected to the hydraulic supply unit HAU3 via piping. A piston PST may be disposed in the hydraulic space HCS. The piston PST may be connected to the height adjustment plate HAU2 by a hydraulic rod HAB.

The height adjustment plate HAU2 may be connected to a lower portion of the jig JG. When the hydraulic supply unit HAU3 supplies a fluid into the hydraulic space HCS, the piston PST may be elevated to allow the height adjustment plate HAU2 to rise. Accordingly, the positions of the jig JG and the adjustment unit ADB in the third direction DR3 may be raised.

Conversely, when the hydraulic supply unit HAU3 discharges the fluid from the hydraulic space HCS, the piston PST may be lowered to allow the height adjustment plate HAU2 to be lowered. Accordingly, the pistons PST of the jig JG and the adjustment unit ADB in the third direction DR3 may be lowered.

In the mask assembly MKA according to the second embodiment of the inventive concept, the position of the support rod RD in the third direction DR3 may be adjusted by operating the height adjustment unit HAU. That is, the support rod RD may be moved toward the mask support MST so that the support rod RD may contact the lower portion of the mask support MST. Afterwards, the adjustment unit ADB may be operated to increase the tensile force of the support rod RD. The support rod RD with the increased tensile force may support the central portion of the mask support MST to remain flat while contacting the lower portion of the mask support MST.

The deposition material jetted from the crucible CR and the nozzle NZ may be deposited at the designed position on the substrate SUB through the opening hole MST1 of the mask support MST and the cell SMK1 of the shadow mask SMK.

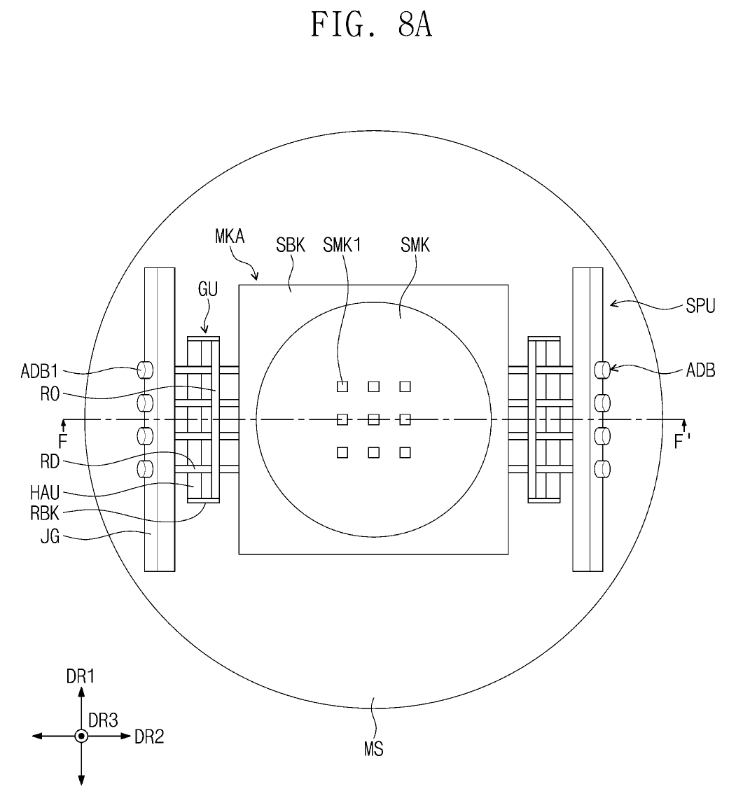

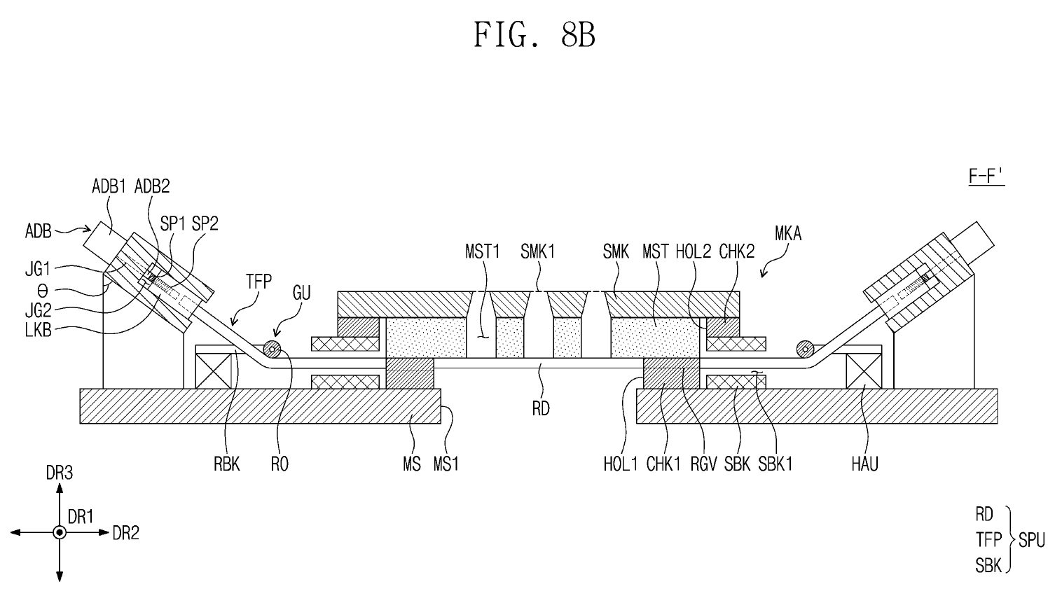

FIG. 8A is a plan view of a mask assembly according to a third embodiment of the inventive concept. FIG. 8B is a cross-sectional view taken along line F-F' shown in FIG. 8A.

Referring to FIGS. 8A and 8B, a mask assembly MKA according to the third embodiment of the inventive concept may include a shadow mask SMK, a mask support MST, a first fixing chuck CHK1, a second fixing chuck CHK2, and a support unit.

Since the configuration of the shadow mask SMK, the mask support MST, the first fixing chuck CHK1, and a second fixing chuck CHK2 is the same as that described in the first embodiment, the above descriptions will be similarly applied thereto.

Additionally, the support unit SPU may include a support rod RD and a tensile force adjustment unit TFP, and the tensile force adjustment unit TFP may include a jig JG, a link block LKB, an adjustment unit ADB, a support block SBK, an inclined block JG3, a height adjustment unit HAU, and a guide unit GU. Since the configuration of the support rod RD, the jig JG, the link block LKB, and the adjustment unit ADB is the same as that described in the first embodiment, the above descriptions will be similarly applied thereto.

Hereinafter, the support block SBK, the inclined block JG3, the height adjustment unit HAU, and the guide unit GU are to be described.

The support block SBK may be disposed on the mounting stage MS. A block hole SBK1 may be defined in the support block SBK along a second direction DR2. The support rod RD may be disposed passing through the block hole SBK1 and be connected to the link block LKB.

Unlike the first embodiment, the second fixing chuck CHK2 may be disposed on the support block SBK in the mask assembly MKA according to the third embodiment of the inventive concept.

The inclined block JG3 may be disposed on the mounting stage MS. The inclined block JG3 may include an upper portion formed at a predetermined angle of inclination (θ). The jig JG, the link block LKB, and the adjustment unit ADB may be disposed on the upper portion of the inclined block JG3. According to this structure, the edge portion of the support rod RD may be bent at the predetermined angle of inclination (θ) and connected to the link block LKB.

The height adjustment unit HAU may be disposed on the mounting stage MS. The guide unit GU may be disposed on the height adjustment unit HAU. The height adjustment unit HAU may adjust the height of the guide unit GU.

Since the jig JG and the link block LKB are disposed on the inclined block JG3, the edge portion of the support rod RD may be disposed higher than the central portion of the support rod RD.

Accordingly, the support rod RD may be bent while being in contact with the guide unit GU, and the central portion of the support rod RD may be disposed parallel to the second direction DR2 under the mask support MST.

Since the support rod RD contacts the guide unit GU, the height adjustment unit HAU may adjust the height of the guide unit GU, and the distance between the support rod RD and the mask support MST may be adjusted.

In an embodiment, when the support rod RD is not in contact with the lower portion of the mask support MST, it is possible to move the support rod RD toward the mask support MST by adjusting the height of the guide unit GU, for example. Thereafter, the central portion of the support rod RD may contact the lower portion of the mask support MST.

The height adjustment unit HAU may be implemented with various driving devices capable of adjusting the height.

In an embodiment, the height adjustment unit HAU may be implemented with a structure of a hydraulic cylinder HAU1 and a height adjustment plate HAU2 shown in FIG. 10. In this case, the guide unit GU may be disposed on the height adjustment plate HAU2. The method of operating the hydraulic cylinder HAU1 and the height adjustment plate HAU2 is similar to the description above.

The guide unit GU may be disposed on the mounting stage MS and guide the direction in which the support rod RD is tensioned.

The guide unit GU may include a roller bracket RBK and a roller RO. The roller bracket RBK may be disposed on the height adjustment plate HAU2 of the height adjustment unit HAU. The roller RO may be rotatably disposed on the roller bracket RBK, and the roller RO may contact an upper portion of the support rod RD.

As described above, since the jig JG, the link block LKB, and the adjustment unit ADB are disposed to form a predetermined angle of inclination (θ), the edge portion of the support rod RD may be bent upward. In this case, the roller RO may support the upper portion of the support rod RD and guide a bent portion of the support rod RD.

Specifically, the roller RO may make the central portion of the support rod RD remain flat so as to stably support the lower portion of the mask support MST, and the edge portion of the support rod RD may be bent to be connected to the link block LKB.

In the mask assembly MKA according to the third embodiment of the inventive concept, the position of the guide unit GU along the third direction DR3 may be adjusted by operating the height adjustment unit HAU. Accordingly, the central portion of the support rod RD may be moved toward the mask support MST so that the central portion of the support rod RD contacts the lower portion of the mask support MST. Afterwards, the tensile force of the support rod RD may be increased by operating the adjustment unit ADB. The support rod RD with increased tensile force may support the central portion of the mask support MST to remain flat while the support rod RD contacts the lower portion of the mask support MST.

In this case, the roller RO may guide the bent portion of the support rod RD. That is, the central portion of the support rod RD may remain flat to stably support the lower portion of the mask support MST. The edge portion of the support rod RD may be bent by the roller RO and be connected to the link block LKB.

Thereafter, the deposition material jetted from the crucible CR and the nozzle NZ may be deposited at the designed position on the substrate SUB through the opening hole MST1 of the mask support MST and the cell SMK1 of the shadow mask SMK.

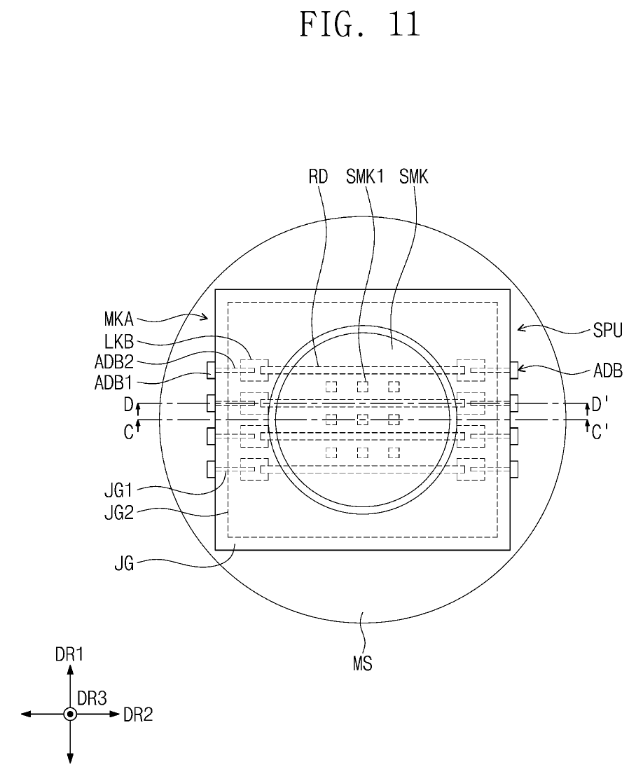

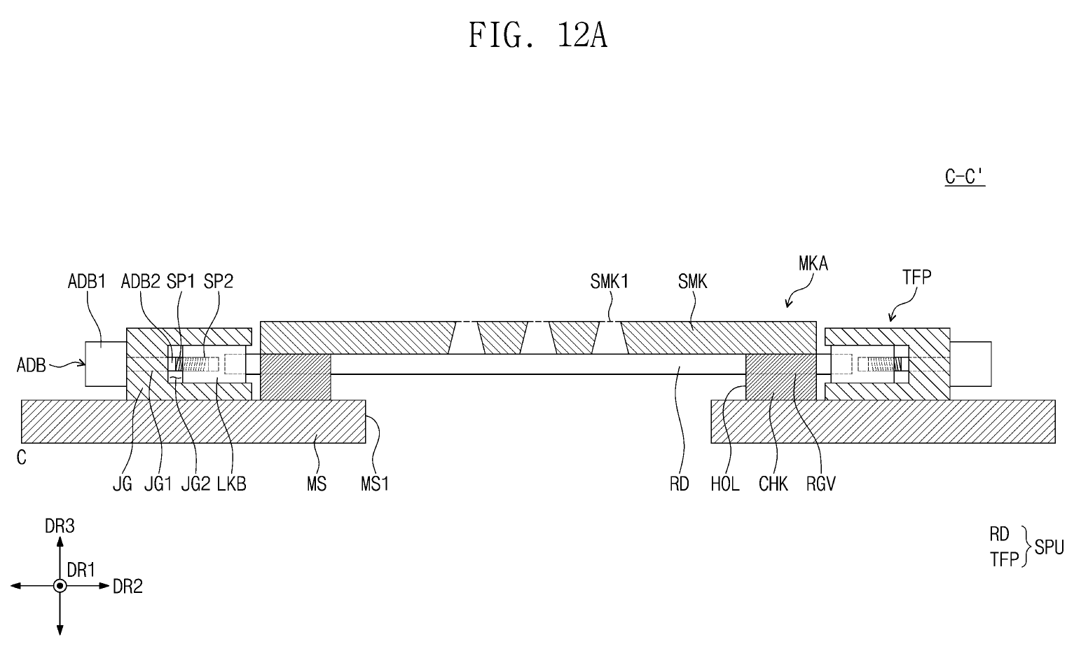

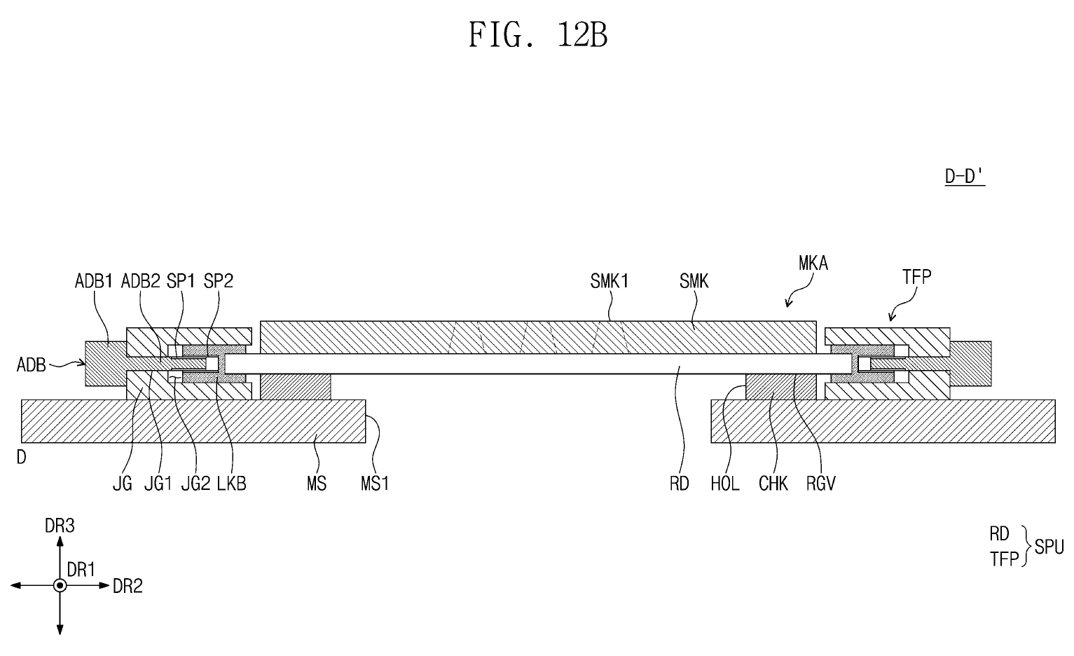

FIG. 11 is a plan view of the mask assembly MKA according to the second embodiment of the inventive concept. FIG. 12A is a cross-sectional view taken along line C-C' shown in FIG. 11. FIG. 12B is a cross-sectional view taken along line D-D' shown in FIG. 11.

Referring to FIGS. 11 to 12B, the mask assembly MKA may include the shadow mask SMK, the fixing chuck CHK, and the support unit SPU.

The fixing chuck CHK may be disposed on the mounting stage MS. A chuck hole HOL may be defined in a central portion of the fixing chuck CHK.

The fixing chuck CHK may be an electrostatic chuck, a magnetic chuck, or the like. When the fixing chuck CHK is the electrostatic chuck, the fixing chuck CHK may include an electrode and the fixing chuck may attract or suction the shadow mask SMK by an electrostatic force. When the fixing chuck CHK is the magnetic chuck, the fixing chuck CHK may include an electromagnet and the fixing chuck CHK may attract or suction the shadow mask SMK by a magnetic force. In addition, the first fixing chuck CHK1 may include various devices capable of fixing the shadow mask SMK by attracting or suctioning the shadow mask SMK.

Additionally, the fixing chuck CHK may be substantially disk-shaped but is not limited thereto. Accommodation grooves RGV may be defined in the fixing chuck CHK along a second direction DR2. The support rods RD may be accommodated in the accommodation grooves RGV. The number of the accommodation grooves RGV may correspond to the number of the support rods RD.

The shadow mask SMK may be attracted or suctioned by the fixing chuck CHK. At least one or more cells SMK1 may be formed in the shadow mask SMK. The deposition material jetted from the nozzle NZ may pass through the cells SMK1 and be deposited on the substrate SUB.

Referring to FIG. 11, the shadow mask SMK may have a circular shape but is not limited thereto. Additionally, a plurality of mask holes MHOL may be defined in the cell SMK1. The deposition material may be further atomized through the plurality of mask holes MHOL and be deposited on the substrate SUB.

The support unit SPU may be disposed on the mounting stage MS and support a lower portion of the shadow mask SMK. The support unit SPU may adjust the flatness of the shadow mask SMK.

In an embodiment of the inventive concept, the support unit SPU may include the support rod RD and the tensile force adjustment unit TFP.

The support rod RD may be disposed under the shadow mask SMK, and the support rod RD may contact the lower portion of the shadow mask SMK and support the shadow mask SMK to prevent the shadow mask SMK from being sagged due to gravity. In other words, the support rod RD may support the lower portion of the shadow mask SMK so as to maintain the shadow mask SMK to be flat.

In an embodiment of the inventive concept, the support rod RD may have a wire-shape extending in the second direction DR2.

The support rod RD may have various cross-sectional shapes. In an embodiment, the support rod RD may have a circular cross-section, an elliptical cross-section, a quadrilateral cross-section, a polygonal cross-section, or the like, for example. As described above, the support rod RD having a quadrilateral cross-section may be most suitable.

Referring to FIG. 11, in a plan view, the support rod RD may be offset with respect to the cell SMK1. That is, the support rod RD and the cell SMK1 may be disposed in different positions with respect to the third direction DR3. According to this structure, the support rod RD may not obstruct the deposition material from passing through the cell SMK1.

The tensile force adjustment unit TFP may be disposed on the mounting stage MS and be connected to the edge portion of the support rod RD. The tensile force adjustment unit TFP may adjust the tensile force of the support rod RD.

The tensile force adjustment unit TFP may be connected to both edge portions of the support rod RD along the second direction DR2. Accordingly, the tensile force adjustment unit TFP may pull the support rod RD from opposite sides to increase the tensile force of the support rod RD.

The tensile force adjustment unit TFP may include a jig JG, a link block LKB, and an adjustment unit ADB and define a jig hole JG1 and a jig groove JG2.

The jig JG may be disposed on the mounting stage MS. Referring to FIG. 11, in an embodiment of the inventive concept, the jig JG may have a quadrilateral shape in a plan view but is not limited thereto.

The jig hole JG1 may be defined passing through the jig JG in the second direction DR2. The jig hole JG1 may have a circular cross-section to allow a stem part ADB2 of the adjustment unit ADB to rotate.

The jig groove JG2 may be defined inside the jig JG and include an open side that faces the support rod RD.

The link block LKB may be disposed in the jig groove JG2. The link block LKB may move along the second direction DR2 within the jig groove JG2. In an embodiment of the inventive concept, the link block LKB may have a quadrilateral block shape. The edge portion of the support rod RD may be connected to the link block LKB.

The adjustment unit ADB may pass through the jig hole JG1 and be connected to the link block LKB. The adjustment unit ADB may adjust the position of the link block LKB along the second direction DR2.

The adjustment unit ADB may include a head part ADB1, a stem part ADB2, a male screw part SP1, and a female screw part SP2.

The head part ADB1 may be disposed at a side portion of the jig JG. The head part ADB1 may be formed to have a larger size than that of the jig hole JG1.

The stem part ADB2 may be connected to the head part ADB1, and the stem part ADB2 may be connected to the link block LKB through the jig hole JG1. The stem part ADB2 may have a circular cross-section. The diameter of the stem part ADB2 may be equal to, similar to, or slightly smaller than the diameter of the jig hole JG1.

The male screw part SP1 may be disposed on an outer circumferential surface of the stem part ADB2, and the female screw part SP2 may be disposed in the link block LKB. The male screw part SP1 and the female screw part SP2 may be engaged. According to this structure, when the head part ADB1 is rotated, the male screw part SP1 and the female screw part SP2 may be further engaged, and the link block LKB may move toward the head part ADB1. The link block LKB may pull the support rod RD to increase the tensile force of the support rod RD.

Unlike the first embodiment, the mask assembly MKA according to a fourth embodiment of the inventive concept may have a structure in which the support rod RD directly supports the lower portion of the shadow mask SMK.

According to this structure, when the adjustment unit ADB is operated to move the link block LKB, the link block LKB may pull the support rod RD to increase the tensile force of the support rod RD. The support rod RD with the increased tensile force may directly support the lower portion of the shadow mask SMK and may maintain the central portion of the shadow mask SMK to be flat.

The deposition material jetted from the crucible CR and the nozzle NZ may be deposited at a designed position on the substrate SUB through the cell SMK1 of the shadow mask SMK.

FIG. 13 is a diagram illustrating a state in which the deposition material DPM is provided on the substrate SUB by the deposition apparatus DPA illustrated in FIG. 1.

Referring to FIG. 13, the shadow mask SMK may be disposed on the substrate SUB. The substrate SUB may be same as or similar to the substrate SUB illustrated in FIG. 11. For convenience of explanation, it is illustrated that a light-emitting layer EML faces upward and the shadow mask SMK is disposed on the light-emitting layer EML, but in practice, the light-emitting layer EML may be in a flipped state during the deposition process, as in the structure illustrated in FIG. 1. In an embodiment, the light-emitting layer EML may face downward, and the shadow mask SMK may be disposed under the light-emitting layer EML, for example.

A hole control layer HCL is disposed on a first electrode AE, and the shadow mask SMK may be used to form the light-emitting layer EML on the hole control layer HCL. The deposition material DPM may be provided on the hole control layer HCL through the cell SMK1 formed on the shadow mask SMK. The light-emitting layer EML may be formed by the deposition material DPM. In an embodiment, one light-emitting layer EML is formed on the substrate SUB, but in practice, a plurality of light-emitting layers EML may be formed on the substrate SUB.

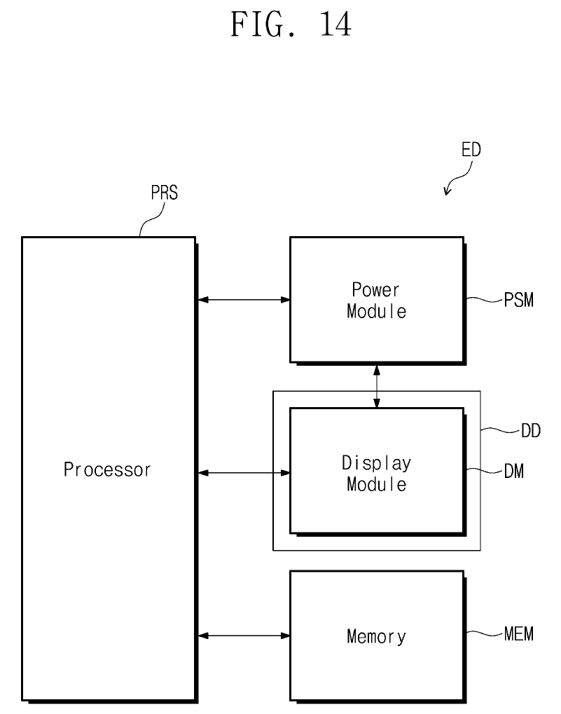

FIG. 14 is a block diagram of an embodiment of an electronic device according to the inventive concept.

Referring to FIG. 14, an electronic device ED in an embodiment may include a display device DD that provides an image to a user, and may further include a module or a device having an additional function other than the display device DD. The electronic device ED in an embodiment may include a display module DM, a processor PRS, a memory MEM, and a power module PSM. The display device DD may include the display module DM.

The processor PRS may include at least one among a central processing unit (“CPU”), an application processor (“AP”), a graphic processing unit (“GPU”), a communication processor (“CP”), an image signal processor (“ISP”), and a controller. The processor PRS processes an image signal and provides the processed image signal to the display device DD, and the display device DD may generate an image corresponding to the image signal.

In an embodiment, the processor PRS may be divided into two or more processors in view of a function or structure. In an embodiment, the processor PRS may include a main processor in the form of a first driving chip including a central processing unit, and an auxiliary processor in the form of a second driving chip including a controller that receives an image signal from the main processor and processes the image signal to comply with the interface specifications of the display module DM, for example.

The memory MEM may store data information desired for the operation of the processor PRS or the display module DM. When the processor PRS executes an application stored in the memory MEM, image data signals and/or input control signals are transmitted to the display module DM, and the display module DM may process the received signals and output image information through a display screen.

The power module PSM may include a power supply module, such as a power adapter or a battery device, and a power conversion module that converts power supplied by the power supply module to generate power desired for the operation of the electronic device ED. The power module PSM may supply power to the display module DM and the processor PRS.

At least one of the components of the electronic device ED described above may be included in the display device DD in the embodiments described above. Additionally, a portion of the individual modules functionally included in one module may be included in the display device DD, and another portion of the modules may be provided separately from the display device DD. In an embodiment, the display device DD may include the display module DM, and the processor PRS, the memory MEM, and the power module PSM may be provided in the form of other devices within the electronic device ED rather than the display device DD, for example.

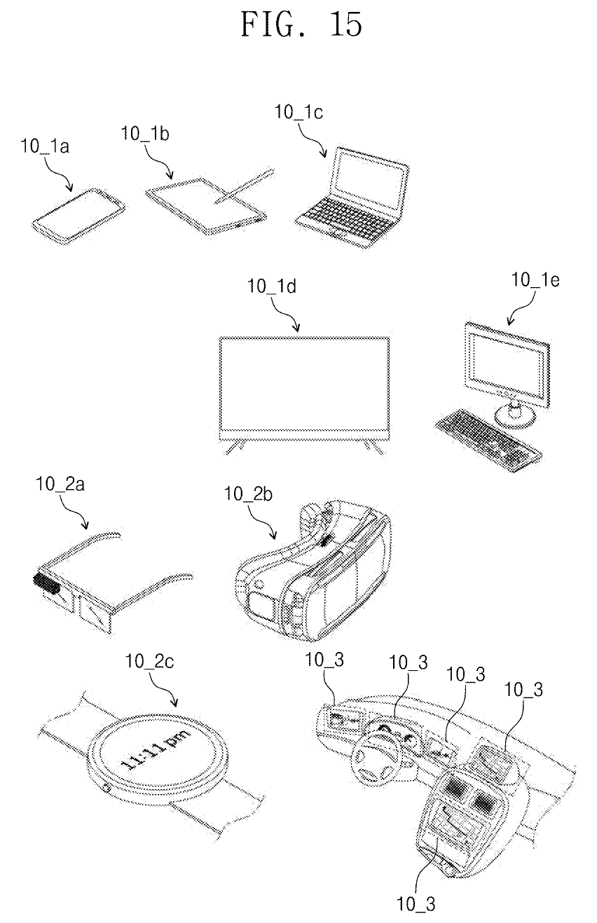

FIG. 15 illustrates schematic views of embodiments of various electronic devices.

Referring to FIG. 15, the display device DD in an embodiment of the inventive concept may be applied to various electronic devices. In an embodiment, various electronic devices, to which the display device DD in an embodiment is applied, may include electronic devices for displaying images, such as a smart phone 10_1a, a tablet personal computer (“PC”) 10_1b, a laptop 10_1c, a television (“TV”) 10_1d, or a desk monitor 10_1e, for example.

Additionally, various electronic devices, to which the display device DD in an embodiment is applied, may include wearable electronic devices such as smart glasses 10_2a, a head-mounted display 10_2b, or a smart watch 10_2c. In addition, various electronic devices, to which the display device DD in an embodiment is applied, may include vehicle electronic devices 10_3 such as a car dashboard, a center fascia, a center information display (“CID”) disposed on a dashboard, or a room mirror display.

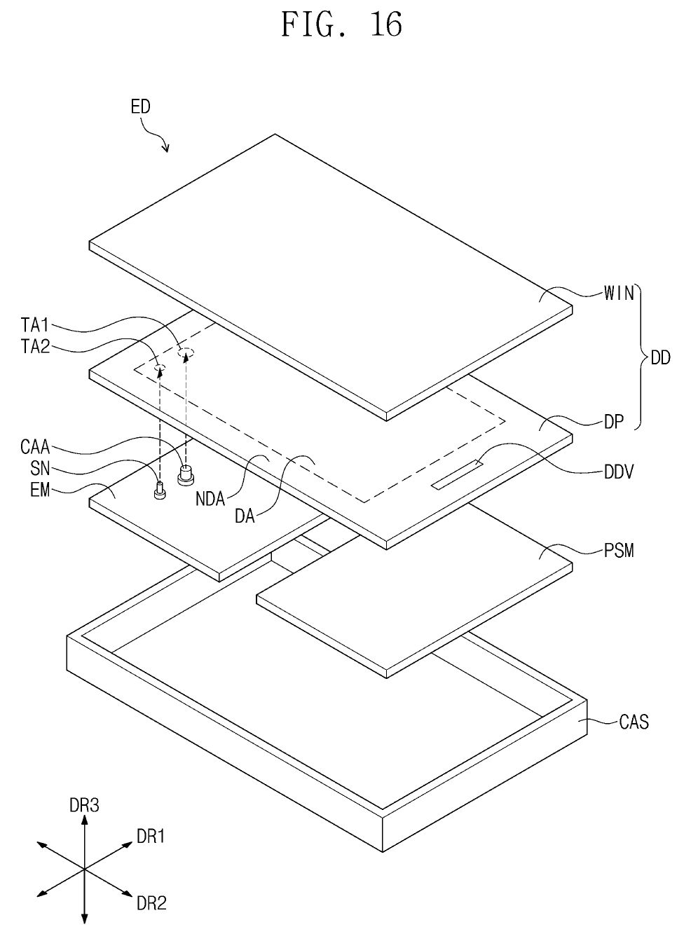

FIG. 16 is an exploded perspective view of an embodiment of an electronic device according to the inventive concept.

Referring to FIG. 16, an electronic device ED may include a display device DD, an electronic module EM, a power module PSM, and a case CAS. The display device DD may include a display module DM and a window WIN disposed on the display module DM.

The electronic module EM and the power module PSM may be disposed under the display device DD. Although not illustrated, the electronic module EM and the power module PSM may be connected to each other through an additional flexible circuit board.

The electronic module EM may control the operation of the display device DD. The electronic module EM may include the processor PRS described above. The power module PSM may supply power to the electronic module EM and the display module DM.

The case CAS may be disposed under the electronic module EM and the power module PSM. The case CAS may accommodate the display device DD, the electronic module EM, and the power module PSM. The case CAS may protect the display device DD, the electronic module EM, and the power module PSM.

The display module DM may include long sides extending in a first direction DR1 and short sides extending in a second direction DR2. The corners of the display module DM may have a round shape.

The display module DM may include a display region DA and a non-display region NDA around the display region DA. The non-display region NDA may surround the display region DA. The display region DA and the non-display region NDA of the display module DM may correspond to the display region DA and the non-display region NDA illustrated in FIG. 3, respectively. The display region DA may generate an image, and the non-display region NDA may not generate an image.

The display module DM may include a display panel DP and a light conversion unit that is disposed on the display panel DP. The display panel DP, as similar to the display module DM, may include the display region DA and the non- display region NDA disposed around the display region DA and surrounding the display region DA. An image may be generated in the display region DA of the display panel DP.

The display panel DP in an embodiment of the inventive concept may be a light-emitting display panel. In an embodiment, the display panel DP may be an organic light-emitting display panel, or an inorganic light-emitting display panel, for example. A light-emitting layer of the organic light-emitting display panel may include an organic light-emitting material. A light-emitting layer of the inorganic light-emitting display panel may include quantum dots, quantum rods, or the like. Hereinafter, the display panel DP is described as an organic light-emitting display panel.

A light conversion unit may receive light generated from the display panel DP and convert the color of the received light. Additionally, the light conversion unit may reduce external light reflectance. This configuration will be described in detail below.

The window WIN may have an optically transparent property. In an embodiment, the window WIN may include glass or transparent plastic, or the like. The window WIN may protect the display module DM from an external impact and a scratch. The front surface of the window WIN may correspond to a display surface of the display device DD described above.

The front surface of the window WIN may include a transparent region and a bezel region surrounding the transparent region. The transparent region may transmit light. The bezel region may surround the transparent region and may be printed in a predetermined color to block light. In a plan view, the transparent region may overlap the display region DA, and the bezel region may overlap the non-display region NDA.

An image generated in the display region DA may be provided to an external user through the transparent region. The non-display region NDA may not be exposed to the outside by the bezel region.

Although not illustrated, the display device DD may further include an input sensing unit disposed between the display panel DP and the light conversion unit. The input sensing unit may include a plurality of sensing units (not illustrated) for detecting an external input. The sensing units may detect an external input in a capacitive manner.

The input sensing unit may be manufactured directly on the display panel DP during a process of manufacturing the display panel DP. However, the inventive concept is not limited thereto, and the input sensing unit may be manufactured as a separate panel from the display panel DP and attached to the display panel DP by an adhesive. In an embodiment, first and second transparent regions TA1 and TA2 which respectively corresponding to a camera module CAA and a sensor module SN may be defined in the display panel DP.

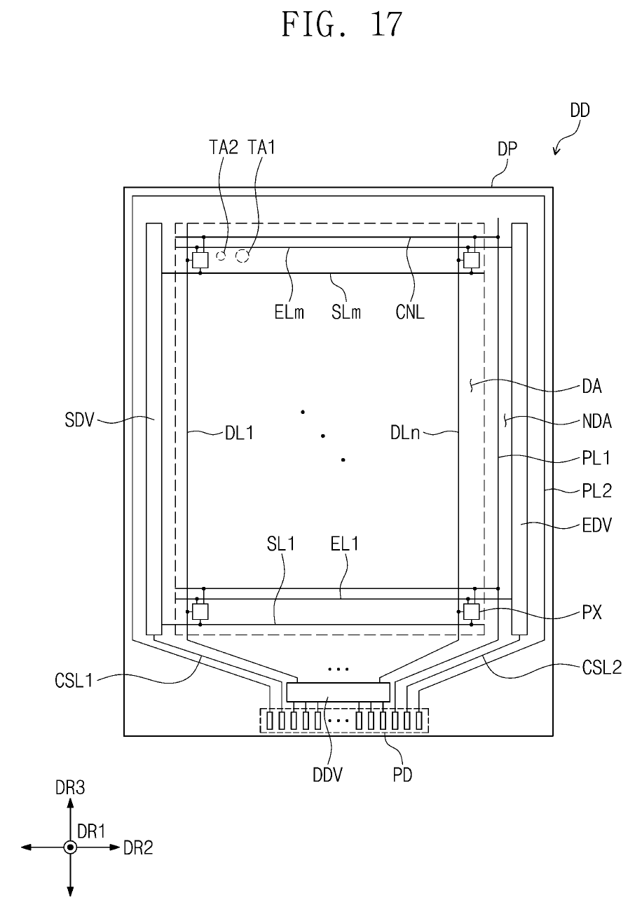

FIG. 17 is a plan view of the display panel illustrated in FIG. 16.

Referring to FIG. 17, the display device may include the display panel DP, a scan driver SDV, a data driver DDV, a light emission driver EDV, and a plurality of pads PD.

The display panel DP may include the display region DA and the non-display region NDA surrounding the display region DA. The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power lines PL1 and PL2, and connection lines CNL. Here, m and n are natural numbers.

The pixels PX may be disposed in the display region DA. The scan driver SDV and the light emission driver EDV may be disposed in the non-display region NDA next (adjacent) to each of the long sides of the display panel DP. The data driver DDV may be disposed in the non-display region NDA next (adjacent) to any one of the short sides of the display panel DP. In a plan view, the data driver DDV may be next (adjacent) to a lower end of the display panel DP.

The scan lines SL1 to SLm may extend in a first direction DR1 to be connected to the pixels PX and the scan driver SDV. The data lines DL1 to DLn may extend in a second direction DR2 to be connected to the pixels PX and the data driver DDV. Emission lines EL1 to ELm may extend in the first direction DR1 to be connected to the pixels PX and the light emission driver EDV.

A first power line PL1 may extend in the second direction DR2 to be disposed in the non-display region NDA. The first power line PL1 may be disposed between the display region DA and the light emission driver EDV.

The connection lines CNL may extend in the first direction DR1 and arranged in the second direction DR2 to be connected to the first power line PL1 and the pixels PX. A first voltage may be applied to the pixels PX through the first power line PL1 and the connection lines CNL that are connected to each other.

A second power line PL2 may be disposed in the non-display region NDA and may extend along the long sides of the display panel DP and a remaining (the other) short side of the display panel DP in which the data driver DDV is not disposed. The second power line PL2 may be disposed outside the scan driver SDV and the light emission driver EDV.

Although not illustrated, the second power line PL2 may extend toward the display region DA and be connected to the pixels PX. A second voltage having a lower level than that of the first voltage may be applied to the pixels PX through the second power line PL2.

A first control line CSL1 may be connected to the scanning driver SDV and extend toward the lower end of the display panel DP. A second control line CSL2 may be connected to the light emission driver EDV and may extend toward the lower end of the display panel DP. The data driver DDV may be disposed between the first control line CSL1 and the second control line CSL2.

The pads PD are disposed in the non-display region NDA next (adjacent) to the lower end of the display panel DP and may be closer to the lower end of the display panel DP than the data driver DDV. The data driver DDV, the first and second power lines PL1 and PL2, and the first and second control lines CSL1 and CSL2 may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling the operations of the scan driver SDV, the data driver DDV, and the light emission driver EDV, and a voltage generator for generating first and second voltages. The timing controller and the voltage generator may be disposed (e.g., mounted) on a printed circuit board and connected to the pads PD through the printed circuit board.

The scan driver SDV generates a plurality of scan signals, and the scan signals may be applied to the pixels PX through the scan lines SL1 to SLm. The data driver DDV generates a plurality of data voltages, and the data voltages may be applied to the pixels PX through the data lines DL1 to DLn. The light emission driver EDV generates a plurality of emission signals, and the emission signals may be applied to the pixels PX through the emission lines EL1 to ELm.

The pixels PX may receive data voltages in response to the scanning signals. The pixels PX may display an image by emitting light with a brightness corresponding to the data voltages in response to emission signals.

FIG. 18 is a drawing illustrating an embodiment of a cross-section of one pixel illustrated in FIG. 17.

Referring to FIG. 18, the pixel PX may include a transistor TR and a light-emitting element OLED connected to the transistor TR. One pixel PX is illustrated in an embodiment, but, in practice, a plurality of pixels PX may be arranged on a substrate SUB.

The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode.

The transistor TR and the light-emitting element OLED may be arranged on the substrate SUB. The planar region of the substrate SUB may be divided into a light-emitting portion PA and a non-light-emitting portion NPA around the light-emitting portion PA. The light-emitting element OLED may be disposed on the light-emitting portion PA.

A buffer layer BFL is disposed on the substrate SUB, and the buffer layer BFL may be an inorganic layer.

Semiconductor patterns S, A, and D may be arranged on the buffer layer BFL. The semiconductor patterns S, A, and D may include polysilicon. However, the inventive concept is not limited thereto, and the semiconductor patterns S, A, and D may include amorphous silicon or a metal oxide.

The semiconductor patterns S, A, and D may be doped with an N-type dopant or a P-type dopant. The semiconductor pattern may include a heavily doped region and a lightly doped region. The heavily doped region has a higher conductivity than that of the lightly doped region and may substantially serve as a source electrode and a drain electrode of the transistor TR. The lightly doped region may substantially correspond to an active (or channel) of the transistor.

A source S, an active A, and a drain D of the transistor TR may be formed from semiconductor patterns S, A, and D. A first insulating layer INS1 may be disposed on the semiconductor patterns S, A, and D. A gate electrode G of the transistor TR may be disposed on the first insulating layer INS1. A second insulating layer INS2 may be disposed on the gate electrode G. A third insulating layer INS3 may be disposed on the second insulating layer INS2.

A connection electrode CNE may be disposed between the transistor TR and the light-emitting element OLED to connect the transistor TR and the light-emitting element OLED. The connection electrode CNE may include a first connection electrode CNE1 and a second connection electrode CNE2.

The first connection electrode CNE1 may be disposed on the third insulating layer INS3 and connected to the drain D through a first contact hole CH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in the fifth insulating layer INS5. A sixth insulating layer INS6 may be disposed on the second connection electrode CNE2. The first to sixth insulating layers INS1 to INS6 may be inorganic layers or organic layers.

The first electrode AE may be disposed on the sixth insulating layer INS6. The first electrode AE may be connected to the second connection electrode CNE2 through a third contact hole CH3 defined in the sixth insulating layer INS6. A pixel-defining layer PDL exposing a predetermined portion of the first electrode AE may be disposed on the first electrode AE and the sixth insulating layer INS6. A pixel opening PX_OP for exposing a predetermined portion of the first electrode AE may be defined in the pixel-defining layer PDL.

The hole control layer HCL may be disposed on the first electrode AE and the pixel-defining layer PDL. The hole control layer HCL may be disposed in common on the light-emitting portion PA and the non-light-emitting portion NPA. The hole control layer HCL may include a hole transport layer and a hole injection layer.

The light-emitting layer EML may be disposed on the hole control layer HCL. The light-emitting layer EML may include an organic material and/or an inorganic material. The light-emitting layer EML may generate any one among red light, green light, and blue light.

The light-emitting layer EML may be manufactured by the deposition apparatus DPA illustrated in FIG. 1. The deposition material may be provided on the substrate SUB through the cell SMK1 of the shadow mask SMK and thus the light-emitting layer EML may be formed.

The electron control layer ECL may be disposed on the light-emitting layer EML and the hole control layer HCL. The electron control layer ECL may be disposed in common on the light-emitting portion PA and the non-light-emitting portion NPA. The electron control layer ECL may include an electron transport layer and an electron injection layer.

The second electrode CE may be disposed on the electron control layer ECL. The second electrode CE may be disposed in common on the pixels PX.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers and an organic layer between the inorganic layers. The inorganic layer may protect the pixel PX from moisture/oxygen. The organic layer may protect the pixel PX from foreign substances such as dust particles.

The first voltage may be applied to the first electrode AE through the transistor TR, and the second voltage having a lower level than that of the first voltage may be applied to the second electrode CE. Holes and electrons injected into the light-emitting layer EML combine to form excitons, and when the excitons transition to the ground state, the light-emitting element OLED may emit light.

The substrate align keys described above may be formed through patterning by the same material as one of the gate electrode G, the first connection electrode CNE1, and the second connection electrode CNE2. The substrate align keys may be disposed at a same layer in which one electrode among the gate electrode G, the first connection electrode CNE1, and the second connection electrode CNE2 is disposed.

In an embodiment of the inventive concept, the flatness of a shadow mask and a mask support supporting the shadow mask may be maintained at a relatively high level. Accordingly, deformation of the shadow mask may not occur. Consequently, a deposition material may be deposited at a designed position on a substrate.

In the above, descriptions have been made with reference to embodiments of the inventive concept, but those skilled in the art that various modifications and changes may be made to the inventive concept without departing from the spirit and scope of the inventive concept set forth in the claims to be described later. In addition, the embodiments disclosed in the inventive concept are not intended to limit the technical idea of the inventive concept, and all technical ideas within the scope of the following claims and their equivalents should be interpreted as being included in the scope of the rights of the inventive concept.

What is claimed is:

1. A deposition apparatus comprising:
a mounting stage; and
a mask assembly disposed on the mounting stage, the mask assembly including:
a first fixing chuck disposed on the mounting stage,
a mask support which is attached on the first fixing chuck and in which an opening hole is defined,
a shadow mask which is disposed on the mask support and in which at least one cell is defined,
a support unit disposed on the mounting stage and supporting a lower portion of the mask support, and
a second fixing chuck disposed on the support unit and to which a lower portion of the shadow mask is attached,
the support unit which adjusts a flatness of the mask support.

2. The deposition apparatus of claim 1, wherein the support unit comprises:
a support rod disposed under the mask support; and
a tensile force adjustment unit disposed on the mounting stage and connected to an edge portion of the support rod,
the tensile force adjustment unit which adjusts a tensile force of the support rod.

3. The deposition apparatus of claim 2, wherein the support rod is wire-shaped.

4. The deposition apparatus of claim 3, wherein the support rod is offset with respect to the opening hole in a plan view.

5. The deposition apparatus of claim 3, further comprising an accommodation groove defined in the second fixing chuck along a second direction,
wherein the support rod is accommodated in the accommodation groove.

6. The deposition apparatus of claim 2, wherein the tensile force adjustment unit comprises:
a jig which is disposed on the mounting stage and in which a jig hole is defined;
a jig groove defined inside the jig and including an open side facing the support rod;
a link block disposed in the jig groove and connected to an edge portion of the support rod; and
an adjustment unit passing through the jig hole and connected to the link block,
the second fixing chuck is disposed on the jig, and
the adjustment unit adjusts a position of the link block along a second direction.

7. The deposition apparatus of claim 6, wherein the adjustment unit comprises:
a head part disposed at a side portion of the jig;
a stem part connected to the head part, passing through the jig hole, and connected to the link block;
a male screw part disposed on an outer circumferential surface of the stem part; and
a female screw part disposed in the link block and engaged with the male screw part.

8. The deposition apparatus of claim 6, wherein the adjustment unit comprises:
a motor disposed on the mounting stage;
a stem part connected to a driving shaft of the motor, passing through the jig hole, and connected to the link block;
a male screw part disposed on an outer circumferential surface of the stem part; and
a female screw part disposed in the link block and engaged with the male screw part.

9. The deposition apparatus of claim 6, wherein, in a plan view, the first fixing chuck is disposed on an outer side of the mask support, and the second fixing chuck is disposed on an inner side of the jig.

10. The deposition apparatus of claim 2, wherein the tensile force adjustment unit comprises:
a support block disposed on the mounting stage;
a height adjustment unit disposed on the mounting stage;
a jig which is disposed on the height adjustment unit and in which a jig hole and a jig groove including an open side facing the support rod are defined;
a link block disposed in the jig groove and connected to an edge portion of the support rod; and
an adjustment unit passing through the jig hole and connected to the link block,
the second fixing chuck is disposed on the support block, and
the adjustment unit adjusts a position of the link block along a second direction.

11. The deposition apparatus of claim 10, wherein the height adjustment unit comprises:
a hydraulic cylinder disposed on the mounting stage; and
a height adjustment plate disposed under the jig and connected to a hydraulic rod of the hydraulic cylinder.

12. The deposition apparatus of claim 10, wherein the tensile force adjustment unit further defines a block hole penetrating the support block in the second direction,
the support rod passing through the block hole and connected to the link block.

13. The deposition apparatus of claim 2, wherein the tensile force adjustment unit comprises:
an inclined block disposed on the mounting stage and including an upper portion formed at a predetermined angle of inclination;
a jig which is disposed over the inclined block and in which a jig hole and a jig groove including an open side facing the support rod are defined;
a link block disposed in the jig groove and connected to the edge portion of the support rod;
a support block disposed on the mounting stage; and
an adjustment unit passing through the jig hole and connected to the link block,
the second fixing chuck is disposed on the support block, and
the adjustment unit adjusts a position of the link block along a second direction.

14. The deposition apparatus of claim 13, wherein the tensile force adjustment unit further comprises a guide unit which is disposed on the mounting stage and guides a direction in which the support rod is tensioned.

15. The deposition apparatus of claim 14, wherein the guide unit comprises:
a roller bracket disposed on the mounting stage; and
a roller rotatably disposed in the roller bracket and in contact with an upper portion of the support rod.

16. The deposition apparatus of claim 15, wherein the tensile force adjustment unit further comprises a height adjustment unit disposed between the mounting stage and the roller bracket, and
the height adjustment unit adjusts positions of the jig and the support rod along a third direction.

17. A deposition apparatus comprising:
a mounting stage; and
a mask assembly disposed on the mounting stage, the mask assembly including:
a fixing chuck disposed on the mounting stage,
a shadow mask which is disposed on the fixing chuck and in which at least one cell is defined, and
a support unit disposed on the mounting stage and supporting a lower portion of the shadow mask,
wherein the support unit adjusts a flatness of the shadow mask.

18. The deposition apparatus of claim 17, wherein the support unit comprises:
a support rod disposed under the shadow mask; and
a tensile force adjustment unit disposed on the mounting stage and connected to an edge portion of the support rod, and
the tensile force adjustment unit adjusts a tensile force of the support rod.

19. The deposition apparatus of claim 18, wherein the tensile force adjustment unit comprises:
a jig which is disposed on the mounting stage and in which a jig hole is defined;
a jig groove defined inside the jig and including an open side facing the support rod;
a link block disposed in the jig groove and including one side portion connected to the edge portion of the support rod; and
an adjustment unit passing through the jig hole and connected to another side portion of the link block, and
the adjustment unit adjusts a position of the link block along second direction.

20. An electronic device comprising:
a processor; and
a display device which receives an image signal from the processor and provides a user with an image corresponding to the image signal, the display device including:
a display panel manufactured by a disposition apparatus which includes:
a mounting stage,
a first fixing chuck disposed on the mounting stage,
a mask support which is attached on the first fixing chuck and in which an opening hole is defined,
a shadow mask which is disposed on the mask support and in which at least one mask hole is defined,
a support unit disposed on the mounting stage and supporting a lower portion of the mask support and adjust a flatness of the mask support, and
a second fixing chuck disposed on the support unit and to which a lower portion of the shadow mask is attached.
